(19) United States
(12) Patent Application Publication
(10) Pub. No.: US 2022/0130899 A1
(43) Pub. Date: Apr. 28, 2022

(54) INTEGRATED MEMS-CMOS ULTRASONIC SENSOR

(71) Applicant: SHENZHEN GOODIX TECHNOLOGY CO., LTD., Shenzhen (CN)

(72) Inventor: Mostafa SOLIMAN, Waterloo (CA)

(21) Appl. No.: 17/477,498

(22) Filed: Sep. 16, 2021

Related U.S. Application Data
(60) Provisional application No. 63/094,920, filed on Oct. 22, 2020.

(51) Int. Cl. H01L 27/20; H01L 41/311; B81B 3/00; H01L 41/113; B81C 1/00

(52) U.S. Cl. CPC H01L 27/20; H01L 41/311; B81B 3/0021; B81B 2201/0292; B81C 1/00246; B81C 2201/013; B81C 2203/0714; H01L 41/1132

(57) ABSTRACT

Ultrasonic sensing approaches are described with integrated MEMS-CMOS implementations. Embodiments include ultrasonic sensor arrays for which PMUT structures of individual detector elements are at least partially integrated into the CMOS ASIC wafer. MEMS heating elements are integrated with the PMUT structures by integrating under the PMUT structures in the CMOS wafer and/or over the PMUT structures (e.g., in the protective layer). For example, embodiments can avoid wafer bonding and can reduce other post processing involved with conventional manufacturing of PMUT ultrasonic sensors, while also improving thermal response.

### CROSS-REFERENCES

This application claims the benefit of priority from U.S. Provisional Patent Application No. 63/094,920, titled “MEMS-CMOS ULTRASONIC SENSOR WITH THERMAL STABILIZATION”, filed Oct. 22, 2020, which is hereby incorporated by reference in its entirety.

### TECHNICAL FIELD

This disclosure relates to ultrasonic sensors, and, more particularly, to integrating micro-electromechanical system (MEMS) and complementary metal-oxide semiconductor (CMOS) ultrasonic sensor components into integrated MEMS-CMOS ultrasonic sensor elements, for example, to implement small fingerprint sensors for integration into portable electronic devices.

### BACKGROUND

Various sensors can be implemented in electronic devices or systems to provide certain desired functions. Some sensors detect static types of user information, such as fingerprints, iris patterns, etc. Other sensors detect dynamic types of user information, such as body temperature, pulse, etc. The various types of sensors can be used for many different purposes. In some cases, such sensors help enable user authentication, for example, to protect personal data and/or prevent unauthorized access to user devices. In other cases, such sensors can help monitor changes in physical and/or mental state of a user, such as for fitness tracking, biofeedback, etc. To support these and other purposes, various types of sensors can be in communication with, or even integrated with, devices and systems, such as portable or mobile computing devices (e.g., laptops, tablets, smartphones), gaming systems, data storage systems, information management systems, large-scale computer-controlled systems, and/or other computational environments.

As one set of examples, authentication on an electronic device or system can be carried out through one or multiple forms of biometric identifiers, which can be used alone or in addition to conventional password authentication methods. A popular form of biometric identifiers is a person's fingerprint pattern. A fingerprint sensor can be built into the electronic device to read a user's fingerprint pattern so that the device can only be unlocked by an authorized user of the device through authentication of the authorized user's fingerprint pattern. Another example of sensors for electronic devices or systems is a biomedical sensor that detects a biological property of a user, e.g., a property of a user's blood, the heartbeat, in wearable devices like wrist band devices or watches. In general, different sensors can be provided in electronic devices to achieve different sensing operations and functions. Such sensing operations and functions can be used as stand-alone authentication methods and/or in combination with one or more other authentication methods, such as a password authentication, or the like.

Different types of sensors have been integrated in different ways, and to different extents, with mobile electronic devices. For example, many modern smart phones have integrated accelerometers, cameras, and even fingerprint sensors. However, each such sensor integration has involved careful consideration of and compliance with technical, design, and other constraints, such as imposed limits on physical space, power, heat generation, cost, external access (e.g., for sensors relying on physical contact or optical access), interference with interface elements (e.g., a display screen, buttons, etc.), etc.

### SUMMARY

Systems and methods are provided for integrating micro-electromechanical system (MEMS) and complementary metal-oxide semiconductor (CMOS) components into integrated MEMS-CMOS ultrasonic sensor elements. Such integrated MEMS-CMOS sensor element designs can avoid certain conventional wafer bonding and related concerns by integrating some or all of the MEMS sensor components into a CMOS ASIC wafer. Some implementations reduce, or eliminate, post processing associated with formation of the PMUT detector elements. Some embodiments further include integrated temperature stabilization.

### BRIEF DESCRIPTION OF THE DRAWINGS

The accompanying drawings, referred to herein and constituting a part hereof, illustrate embodiments of the disclosure. The drawings together with the description serve to explain the principles of the invention.

FIG. 1 shows a block diagram of a sensor environment as context for various embodiments described herein.

FIGS. 2A and 2B show an example of a portable electronic device having a sensing system integrated as an under-display sensor, according to various embodiments.

FIG. 3 shows illustrative detail for a conventional type of ultrasonic sensor, which is used in some conventional ultrasonic fingerprint sensor implementations.

FIGS. 4A-4F show an illustrative technique for fabricating embodiments of an integrated micro-electromechanical system and complementary metal-oxide semiconductor (MEMS-CMOS) ultrasonic sensor element, according to a first set of embodiments.

FIGS. 5A-5C show an illustrative technique for fabricating embodiments of an integrated MEMS-CMOS ultrasonic sensor element, according to a second set of embodiments.

FIGS. 6A-6C show an illustrative technique for fabricating embodiments of an integrated MEMS-CMOS ultrasonic sensor element, according to a third set of embodiments.

FIG. 7 shows a flow diagram of an illustrative method for manufacturing an integrated MEMS-CMOS ultrasonic sensor element, according to various embodiments described herein.

FIGS. 8A and 8B show side and top views, respectively, of a first illustrative implementation of a novel integrated MEMS-CMOS ultrasonic sensor element with integrated temperature stabilization.

FIG. 9 shows a second illustrative implementation of a novel integrated MEMS-CMOS ultrasonic sensor element with integrated temperature stabilization.

FIG. 10 shows a third illustrative implementation of a novel integrated MEMS-CMOS ultrasonic sensor element with integrated temperature stabilization.

FIG. 11 shows a fourth illustrative implementation of a novel integrated MEMS-CMOS ultrasonic sensor element with integrated temperature stabilization.

FIG. 12 shows a flow diagram of an illustrative method for manufacturing a piezoelectric micromachined ultrasonic transducer (PMUT), according to various embodiments described herein.

In the appended figures, similar components and/or features can have the same reference label. Further, various components of the same type can be distinguished by following the reference label by a second label that distinguishes among the similar components. If only the first reference label is used in the specification, the description is applicable to any one of the similar components having the same first reference label irrespective of the second reference label.

### DETAILED DESCRIPTION

In the following description, numerous specific details are provided for a thorough understanding of the present invention. However, it should be appreciated by those of skill in the art that the present invention may be realized without one or more of these details. In other examples, features and techniques known in the art will not be described for purposes of brevity.

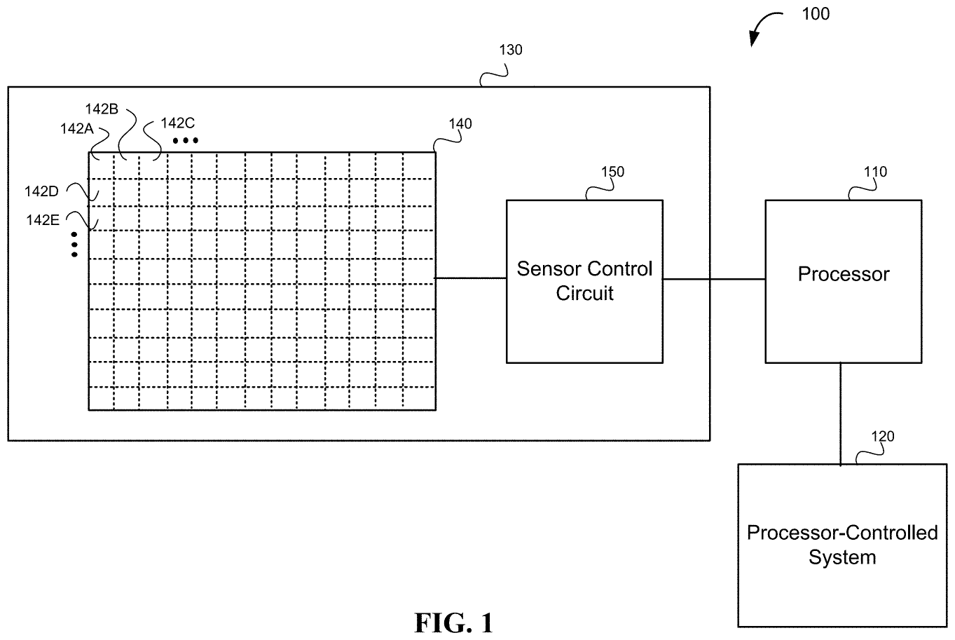

Turning to FIG. 1, a block diagram is shown of a sensor environment 100 as context for various embodiments described herein. The sensor environment 100 is illustrated as including a processor-controlled system 120 and an ultrasonic sensor system 130. The processor-controlled system 120 is intended generally to represent any suitable system or systems to provide any suitable features of the sensor environment 100, other than those of the ultrasonic sensor system 130. For example, in a smart phone, the processor-controlled system 120 can include subsystems for providing telephonic and communications features, display features, user interaction features, application processing features, etc. Embodiments of the sensor environment 100 can include one or more processors 110. In some embodiments, the one or more processors 110 are shared between the processor-controlled system 120 and the ultrasonic sensor system 130. In other embodiments, one or more processors 110 are used by the processor-controlled system 120, and the ultrasonic sensor system 130 has its own one or more dedicated processors 110.

Embodiments of the ultrasonic sensor system 130 include a sensor array 140 and a sensor control circuit 150. The sensor array 140 can be implemented as an array of ultrasound transducers. Each ultrasound transducer, or groups of transducers, can be considered as a detector element 142. The sensor control circuit 150 can direct the detector elements 142 to transmit and receive ultrasonic signals. In some embodiments, some or all of the sensor array 140 includes acoustic transducers structured to function both as the acoustic wave source (acoustic transmitters) and as the returned acoustic signal receiver (acoustic receivers). In other embodiments, some or all of the sensor array 140 includes acoustic wave transmitters and returned acoustic signal wave receivers that are separate ultrasound transducers.

Each detector element 142 (or each acoustic receiver detector element 142) can detect responses to the ultrasonic signaling, such as reflected acoustical signal information. For example, in context of a fingerprint sensor, a finger is places on a detection surface and is bombarded with ultrasonic waves. The ultrasonic waves tend to pass through (e.g., be absorbed by, scattered by, etc.) fingerprint skin in contact with detection surface, but tend to be reflected when encountering air at the detection surface. As such, reflections tend to be weaker in regions of fingerprint ridges (where the skin is contacting the surface) than in regions of fingerprint troughs (where no skin is contacting the surface). By mapping the detector elements 142 to respective physical locations in the sensor array 140, detected ultrasonic responses can be used effectively to generate pixels (or groups of pixels) of imaging information. The pixels of imaging information can be passed by the sensor control circuit 150 to the processor(s) 110, or otherwise used to generate useful output data, such as a fingerprint image.

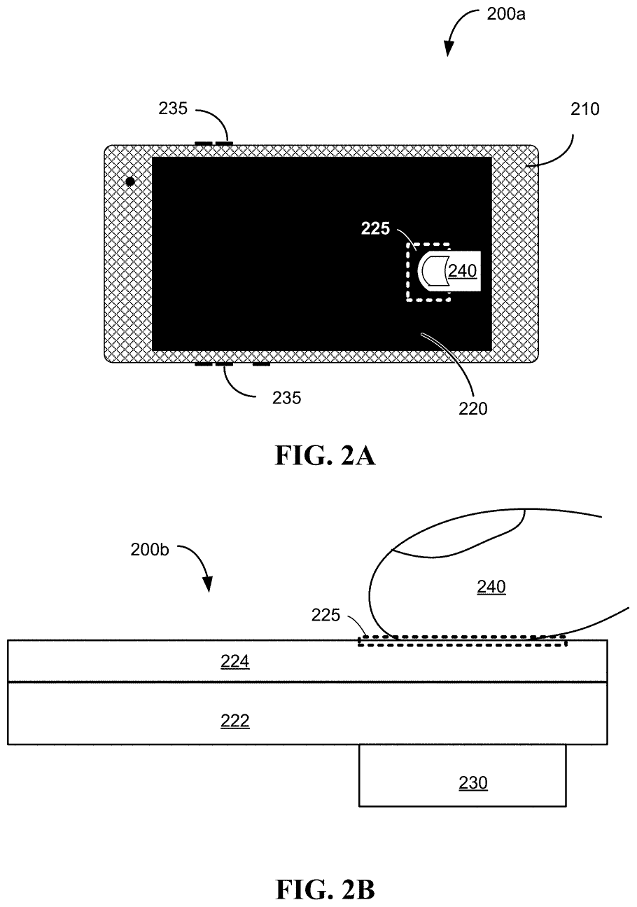

For the sake of illustration, FIGS. 2A and 2B show an example of a portable electronic device 200 having a sensing system 130 integrated as an under-display sensor 230, according to various embodiments. The portable electronic device 200 can be an embodiment of the sensor environment 100 of FIG. 1, such as by integrating the sensor environment 100 in a smart phone. For example, a single portable electronic device 200 can include one or more integrated ultrasonic sensor systems 130 as fingerprint sensors, blood pressure or heart rate sensors, and/or for other purposes. Though illustrated as a smart phone, the portable electronic device 200 can be implemented as any suitable portable electronic device 200, such as a tablet computer, a laptop computer, an electronic reader, a wrist-worn or other wearable device, etc. Further, though illustrated as a portable device, embodiments of the ultrasonic sensors described herein can also be implemented in non-portable devices, such as access control systems, automated teller machines, etc.

As illustrated by the top view of the portable electronic device 200 (designated by reference designator 200a in FIG. 2A), embodiments of the portable electronic device 200 include a housing 210 that integrates various features, such as a display screen 220 and one or more physical buttons 235. Any other suitable interface elements can be included in the portable electronic device 200 and integrated with (or within) the housing 210. In such an environment, the ultrasonic sensor system 130 can be implemented in any suitable location and/or integrated with any suitable components. For example, the ultrasonic sensor system 130 can be integrated with a physical button, in a dedicated location around the periphery of the display 220, on the underside or edge of the portable electronic device 200, etc. In some embodiments, as illustrated, the ultrasonic sensor system 130 is implemented as an under-display sensor 230. In such an implementation, the ultrasonic sensor system 130 is disposed under the display 220 and configured to use a dedicated portion of the display 220 as a detection region 225.

For example, as illustrated by the side view of the portable electronic device 200 (designated by reference designator 200b in FIG. 2B), the display screen 220 can include multiple layers, including multiple functional display layers 222 and a top cover layer 224. The multiple functional display layers 222 can implement any suitable type of display, such as a liquid crystal display (LCD), an organic light-emitting diode (OLED) display, a quantum light-emitting diode (QLED) display, a touch-sensitive display (e.g., to implement a capacitive touch-screen), etc. The top cover layer 224 can be any suitable transparent and/or protective layer disposed over the multiple functional display layers 222. In some embodiments, the top cover layer 224 is configured to provide certain features, such as transmission and/or conduction characteristics to support optical features, acoustical features, capacitive features, pressure-sensing features, and/or other features of the display screen 220. Embodiments of the under-display sensor 230 can be installed under some or all of the multiple functional display layers 222. For example, the detector elements 142 of the sensor array 140 are configured to transmit ultrasonic waves in the direction of the detection region 225 through the functional display layers 222 and the top cover layer 224 (on which a finger 240 may be placed), and are configured to detect reflected ultrasonic information from the detection region 225 back through the top cover layer 224 and the functional display layers 222.

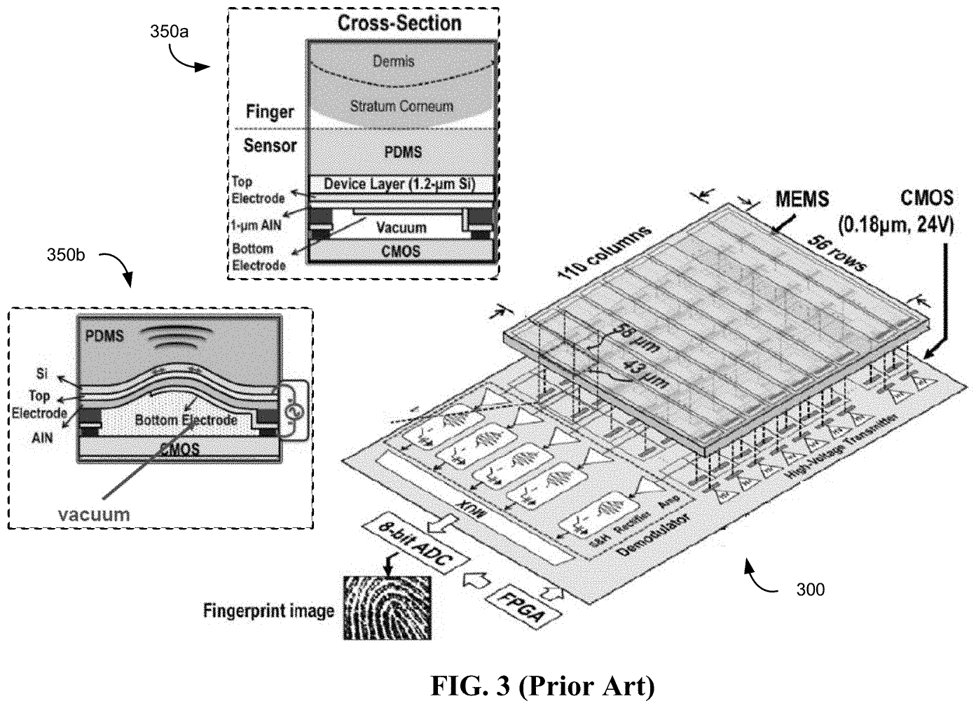

FIG. 3 shows illustrative detail for a conventional type of ultrasonic sensor 300, which is used in some conventional ultrasonic fingerprint sensor implementations. An example of such a conventional ultrasonic sensor 300 (including descriptions of its fabrication and integration into portable electronic devices) is described in U.S. patent application Ser. No. 15/968,420, titled “Ultrasound Fingerprint Sensing and Sensor Fabrication.” Such conventional ultrasonic sensors 300 tend to be fabricated by manufacturing an application-specific integrated circuit (ASIC) (e.g., as a complimentary metal-oxide semiconductor (CMOS) structured chip), and adding the MEMS ultrasonic sensor components to the ASIC. For example, the manufactured CMOS ASIC is finished with a passivation layer, or the like, and additional components are coupled with the wafer only via contacts (e.g., pads, etc.) intentionally left exposed as part of the manufacturing process. Such subsequent addition of the sensor components to the fabricated ASIC is generally referred to in the art as “post processing” the ASIC. In some such post processing implementations, a micro-electromechanical system (MEMS) sensor wafer is separately manufactured, and the MEMS wafer is wafer-bonded (e.g., using Eutectic bonding) to the CMOS ASIC to form the ultrasonic sensor 300. In other such post processing implementations, MEMS components are bonded directly to the CMOS ASIC.

For example, the ultrasound transducers can be arranged in a sensing array built on the CMOS ASIC by preparing the electrodes for each transducer element on the ASIC. A single piece, or several large pieces, of ultrasonic transducer materials (e.g., a piezoelectric material) are bounded or coated onto the ASIC. Corresponding electrodes can be connected. The transducer materials are diced or etched to render the discrete ultrasonic transducer elements. Such a design can be configured to realize proper resonant frequency. Gaps among discrete ultrasonic transducer elements can be filled with an appropriate filler material, such as a proper epoxy. The top electrodes of the discrete ultrasonic transducers can then be formed. According to a driving mode, each top electrode can include a single, or several, or a row, or a column of discrete ultrasonic transducer elements. When high voltage is applied to the transducers, ultrasonic waves are generated. For example, a low voltage circuit is connected to the transducers to receive the returned ultrasonic wave induced electric signals. For some implementations using separate transmitting and sensing transducers, separate ultrasound transducer layer structures can be fabricated (e.g., for generating the ultrasound signals and for sensing the ultrasound signals, respectively). For example, in some implementations, a top layer structure is an acoustic signal receiver having ultrasound sensing transducers to detect returned ultrasound signals, and a separate bottom layer structure is an acoustic signal generator having ultrasound emitter transducers to generate the ultrasound signals towards the top sensing area. Some implementations (e.g., in which transducers are configured both to generate and to sense ultrasound signals) further include on-board circuitry (e.g., as part of the sensor control circuit 150) to controlling the transmission and reception functions, such as including a multiplexed driver and receiver architecture.

Two cross-sectional images 350 are shown of an illustrative conventional detector element of the conventional ultrasonic sensor 300. As shown in image 350a, the detector element includes a CMOS ASIC as a bottom layer. The MEMS sensor is then produced by bonding a bottom electrode to the ASIC, building a piezoelectric material layer onto the bottom electrode, and building a top electrode onto the piezoelectric material layer. The MEMS sensor components form a Piezoelectric Micromachined Ultrasonic Transducer (PMUT) detector element. In a typical application (e.g., the application illustrated by FIGS. 2A and 2B), the PMUT detector element can be disposed under one or more device layers, and a silicone layer (e.g., Polydimethylsiloxane (PDMS)), or the like. For context, a ridge of a fingertip is shown in contact with a top surface of the silicone layer.

As shown in image 350b, during transmission, electrical pulses are applied to the electrodes, causing the piezoelectric material layer to mechanically deform, thereby vibrating the air in accordance with an ultrasonic acoustical signal. It can be seen in both images 350 that the PMUT is manufactured so as to preserve or form a low-pressure (e.g., vacuum) gap below the bottom electrode. Such a gap can help direct the ultrasonic energy toward the silicone layer and away from the CMOS ASIC. During receipt, reflected acoustical waves cause mechanical deformation of the piezoelectric material layer, which induces electrical signals. The generated electrical signals can then be processed to obtain desired data. For example, as illustrated, the ultrasonic sensor 300 can convert the analog electrical signals into digital data, which can be used to produce a fingerprint image, or any other suitable data.

Various concerns can be attributed to the types of post processing used by conventional approaches, such as that of ultrasonic sensor 300. One such concern is that separate wafer processing tends to be performed by different fabricators in different facilities. For example, the CMOS ASIC can be produced by a traditional CMOS foundry, while the PMUT tends to be produced by a specialized MEMS fabricator. Separate fabrication can cause misalignment and related issues, and addressing such issues can increase manufacturing costs and lead times, can drive increased manufacturing tolerances, etc. Further, relying on post processing can increase occurrences of bonding deficiencies (particularly in mass production, and particularly with separate wafer manufacturers). Further, dicing the bonded wafers can produce leaks in the low-pressure gaps of the PMUT, the bonding material can add electrical resistance and/or other parasitics, and/or the bonding can otherwise reduce performance of the sensors. Further, the bonding can tend to add height to the sensors.

Embodiments described herein include various novel techniques for integrating micro-electromechanical system (MEMS) and complementary metal-oxide semiconductor (CMOS) components into an integrated MEMS-CMOS design. Such integrated MEMS-CMOS designs can avoid wafer bonding and related concerns by integrating some or all of the MEMS sensor components into the CMOS ASIC wafer. Some implementations reduce, or eliminate, post processing associated with formation of the PMUT detector elements.

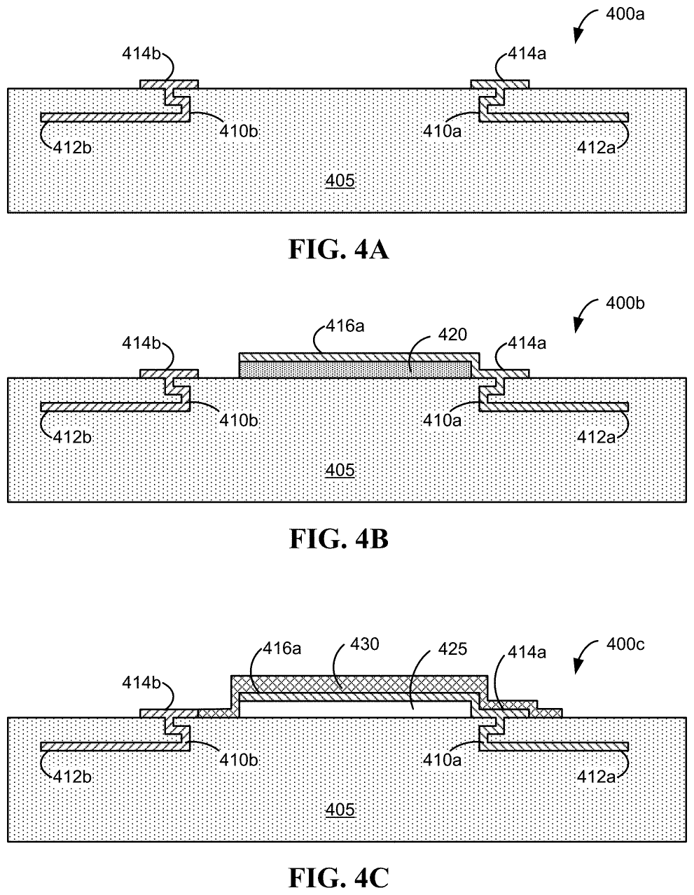

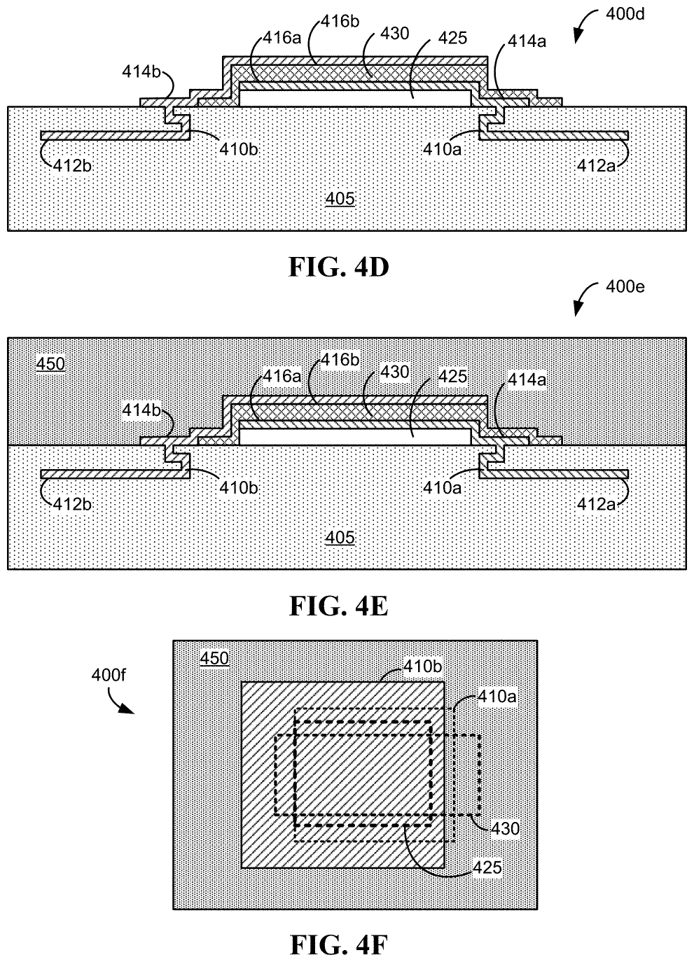

FIGS. 4A-4F show an illustrative technique for fabricating embodiments of an integrated MEMS-CMOS ultrasonic sensor element 400, according to a first set of embodiments. The integrated MEMS-CMOS ultrasonic sensor element 400 can be an implementation of a detector element 142 of the sensor array 140 of FIG. 1. In general, the MEMS sensor components include a “bottom” electrode (e.g., of a first metal), a “top” electrode (e.g., of a second metal), and a piezoelectric transducer. In the embodiments of FIGS. 4A-4F, the integrated MEMS-CMOS ultrasonic sensor element 400 is fabricated by partially integrating first and second electrode paths 410 into a CMOS substrate 405. For example, such integration is performed in a CMOS foundry, or the like, by depositing metal for the electrode paths 410 on metal layers as part of the integrated circuitry of a CMOS wafer.

Integration of the electrode paths 410 includes patterning each electrode path 410 to couple with respective electrode control circuitry (not shown). In some implementations, the electrode control circuitry is also integrated with the CMOS wafer (as part of an integrated circuit chip), and the control end 412 of each electrode path 410 is electrically routed and coupled to its respective control circuitry via electrically conductive paths and/or other components integrated with the CMOS substrate 405. In other implementations, each electrode path 410 is electrically routed and coupled to one or more corresponding input/output nodes (e.g., exposed electrical contacts, electrical pads, pins, solder points, etc.) via electrically conductive paths and/or other components integrated with the CMOS substrate 405, and electrode control circuitry can be electrically coupled with the electrode paths 410 via the corresponding input/output nodes. Integration of the electrode paths 410 also includes fabricating each electrode path 410 to terminate at a respective exposed metal contact 414 at the conclusion of processing of the CMOS wafer. Upon completion of processing of the CMOS wafer (e.g., by a CMOS foundry), there is a pair of exposed metal contacts 414 in the location of each integrated MEMS-CMOS ultrasonic sensor element 400.

Turning to FIG. 4B, after the CMOS wafer is processed, post-processing can be performed to fabricate remaining portions of the integrated MEMS-CMOS ultrasonic sensor element 400. As shown, a sacrificial layer 420 can be deposited on top of the CMOS substrate 405 in the region between the exposed metal contacts 414 of the two electrode paths 410. A first electrode 416a (a bottom electrode, or lower electrode, in the orientation of the drawing) is deposited by deposition of a first metal on top of the sacrificial layer 420. The first metal is deposited so that a portion of the deposited metal is electrically coupled with the first exposed metal contact 414a. In some implementations, the metal of the first electrode 416a is substantially the same as the metal of the exposed metal contact 414, such that the first electrode 416a is effectively an extension of the first electrode path 410a. In some implementations, the first electrode 416a is deposited as a layer of metal between 0.5-1 micron thick, and the sacrificial layer 420 is deposited to be approximately 2 microns thick.

Turning to FIG. 4C, the sacrificial layer 420 can be removed to form an acoustic cavity 425, and a piezoelectric element 430 can be fabricated. The sacrificial layer 420 can be made of silicon oxide, silicon nitride, or any other suitable material to facilitate its removal in order to form the acoustic cavity 425 under the PMUT materials. In some implementations, the first electrode 416a metal is patterned to open small release holes for etching the sacrificial layer 420 underneath, thereby forming the acoustic cavity 425 (e.g., using hydrofluoric acid, or the like).

In some implementations, the acoustic cavity 425 is a “vacuum” cavity. In such implementations, after etching of the acoustic cavity 425, another layer of material is deposited on the first electrode 416a in a conformal layer to seal the release holes created for etching the sacrificial layer 420. In one such implementation, the first electrode 416a metal is deposited as the conformal layer to seal the release holes created for etching the sacrificial layer. In another such implementation, piezoelectric thin film material (e.g., of the piezoelectric element 430) is deposited in the conformal layer to seal the release holes created for etching the sacrificial layer. The depositing of the conformal layer can be performed at low pressure to facilitate creation of the acoustic cavity 425 as a “vacuum” cavity. As used herein, the term “vacuum cavity” is intended to include any cavity of sufficiently low pressure to provide desired acoustic properties in accordance with particular design criteria, even though such a cavity may not be at full vacuum pressure (e.g., at zero or negative pressure). For example, some etching processes are performed in a low-pressure environment, and sealing of the cavity in the same environment (e.g., as part of the same fabrication process) can maintain a pressure in the cavity that is sufficiently low to be considered as a vacuum cavity herein.

The piezoelectric element 430 is formed by depositing a piezoelectric thin film on top of the first electrode 416a (and the acoustic cavity 425). The piezoelectric element 430 is patterned to form the piezoelectric transducer. In some embodiments, the active piezoelectric transducer is formed as a patterned thin-film layer of Aluminum Nitride (AlN), or any other suitable material. In some implementations, the piezoelectric element 430 is approximately one micron thick (e.g., substantially the same thickness of the first electrode 416a. In some implementations, the piezoelectric element 430 contributes to sealing of the acoustic cavity 425.

Turning to FIG. 4D, a second electrode 416b (e.g., a top electrode, or upper electrode, in the orientation of the drawing) is deposited by deposition of a second metal on top of the piezoelectric element 430. The metals of the first and second electrodes 416 can be the same or different. The second metal is deposited so that a portion of the deposited metal is electrically coupled with the second exposed metal contact 414b (i.e., thereby electrically coupling the second electrode 416b with the second electrode path 410b). In some implementations, the metal of the second electrode 416b is substantially the same as the metal of the second exposed metal contact 414b, such that the second electrode 416b is effectively an extension of the second electrode path 410b. In some implementations, the second electrode 416b is deposited as a layer of metal between 0.5-1 micron thick; substantially the same thickness of the first electrode 416a. As such, the first electrode 416a and the second electrode 416b are patterned to form electrode elements with the piezoelectric element 430 sandwiched between them.

Turning to FIG. 4E, in some embodiments, one or more additional layers are deposited on the wafer (illustrated generally as additional layers 450). In some such embodiments, the one or more additional layers 450 include one or more protective layers. For example, in implementations configured for use as a fingerprint sensor, a protective layer can be deposited across the whole wafer that has matched acoustic impedance close to that of human skin. In some implementations, the protective layer is made of polysilicon (e.g., PDMS) and is at least approximately 5-7 microns thick. In some implementations, the surface of the sensor wafer is then planarized and/or otherwise finished.

Turning to FIG. 4F, an illustrative, simplified top view is shown of the integrated MEMS-CMOS ultrasonic sensor element 400 fabricated according to FIGS. 4A-4E. An illustrative pattern of overlap can be seen in the top view, in which the PMUT structures overlap to form a region where the piezoelectric element 430 is sandwiched between the first electrode 416a and the second electrode 416b directly over the acoustic cavity 425.

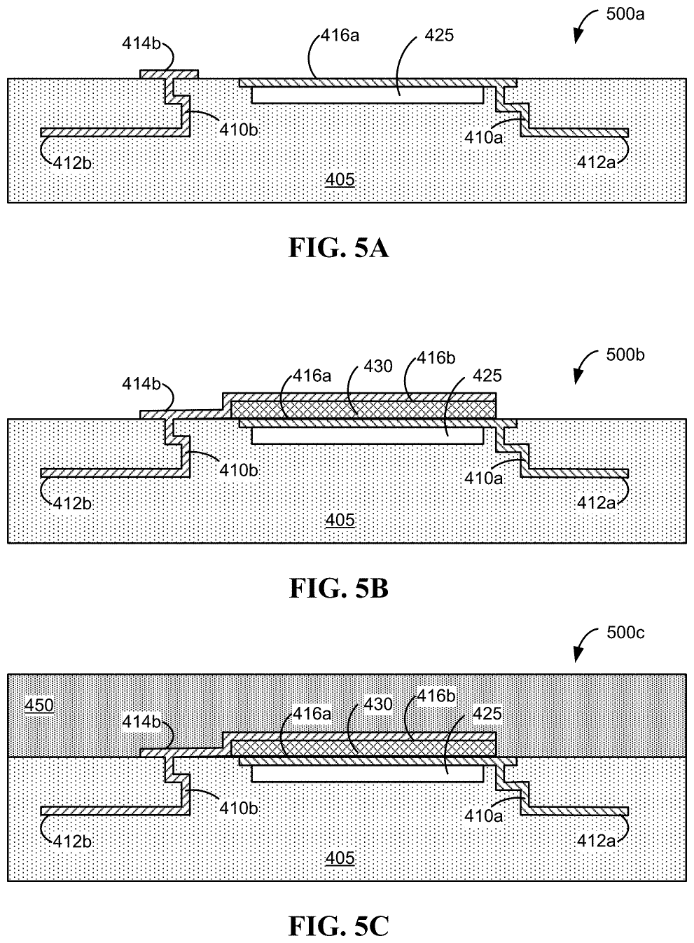

FIGS. 5A-5C show an illustrative technique for fabricating embodiments of an integrated MEMS-CMOS ultrasonic sensor element 500, according to a second set of embodiments. The integrated MEMS-CMOS ultrasonic sensor element 500 can be an implementation of a detector element 142 of the sensor array 140 of FIG. 1. As in FIGS. 4A-4F, the MEMS sensor components generally include a “bottom” electrode (e.g., of a first metal), a “top” electrode (e.g., of a second metal), and a piezoelectric transducer. In the embodiments of FIGS. 5A-5C, the integrated MEMS-CMOS ultrasonic sensor element 500 is fabricated by fully integrating a first electrode path 410 (including the first electrode 416a portion of the first electrode path 410) and partially integrating a second electrode path 410b into a CMOS substrate 405. For example, such integration is performed in a CMOS foundry, or the like, by depositing metal for the electrode paths 410 on metal layers as part of the integrated circuitry of a CMOS wafer.

Integration of the electrode paths 410 includes patterning each electrode path 410 to couple with respective electrode control circuitry (not shown), as described with reference to FIG. 4A. Similar to FIG. 4A, integration of the second electrode path 410b in FIG. 5A includes fabricating the second electrode path 410b to terminate at an exposed metal contact 414b at the conclusion of processing of the CMOS wafer. Unlike in FIG. 4A, FIG. 5A shows fabrication of the full first electrode path 410, including fabrication of the first electrode 416a, as part of processing the CMOS wafer. As illustrated, during fabrication of the CMOS wafer (e.g., at the CMOS foundry), the first electrode 416a metal is deposited and patterned in the last metal layer of the CMOS wafer. Integration of the first electrode 416a can include patterning a sacrificial layer (e.g., of silicon oxide, or the like), depositing the first electrode 416a metal over the sacrificial layer, patterning relief holes in the first electrode 416a, and etching the sacrificial layer using the relief holes to form an acoustic cavity 425 under the first electrode 416a. As described above, a conformal layer (e.g., of the first electrode 416a metal and/or the piezoelectric element 430 material) can be used to seal the relief holes to form the acoustic cavity 425 as a “vacuum” cavity in some implementations. Thus, upon completion of processing of the CMOS wafer, in the location of each integrated MEMS-CMOS ultrasonic sensor element 500, there is a fully formed and exposed first electrode 416a (patterned above an acoustic cavity 425) of a first electrode path 410a, and an exposed metal contact 414b of a second electrode path 410b.

Turning to FIGS. 5B and 5C, after the CMOS wafer is processed, post-processing can be performed to fabricate remaining portions of the integrated MEMS-CMOS ultrasonic sensor element 500. The remaining process of FIGS. 5B and 5C can be similar to that of FIGS. 4C-4E described above. The piezoelectric element 430 can be formed by depositing a piezoelectric thin film on top of the first electrode 416a (and the acoustic cavity 425), and patterning the thin film material to form a piezoelectric transducer. The second electrode 416b (e.g., a top electrode, or upper electrode, in the orientation of the drawing) is deposited by deposition of a second metal on top of the piezoelectric element 430, such that a portion of the deposited metal is electrically coupled with the second exposed metal contact 414b (i.e., thereby electrically coupling the second electrode 416b with the second electrode path 410b). FIG. 5C shows one or more additional layers optionally deposited on the wafer (illustrated generally as additional layers 450). In some implementations, the surface of the sensor wafer is then planarized and/or otherwise finished. The resulting integrated MEMS-CMOS ultrasonic sensor element 500 can be similar to the integrated MEMS-CMOS ultrasonic sensor element 400 of FIGS. 4A-4F, with the PMUT structures overlapping to form a region where the piezoelectric element 430 is sandwiched between the first electrode 416a and the second electrode 416b directly over the acoustic cavity 425.

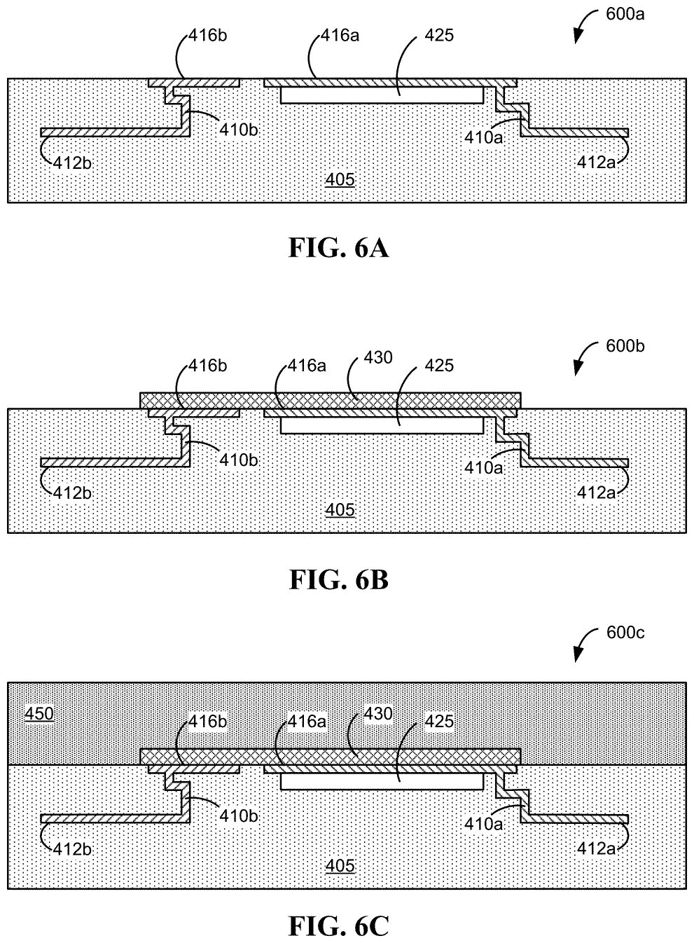

FIGS. 6A-6C show an illustrative technique for fabricating embodiments of an integrated MEMS-CMOS ultrasonic sensor element 600, according to a third set of embodiments. The integrated MEMS-CMOS ultrasonic sensor element 600 can be an implementation of a detector element 142 of the sensor array 140 of FIG. 1. As in FIGS. 4A-5C, the MEMS sensor components generally include a “bottom” electrode (e.g., of a first metal), a “top” electrode (e.g., of a second metal), and a piezoelectric transducer. In the embodiments of FIGS. 6A-6C, the integrated MEMS-CMOS ultrasonic sensor element 600 is fabricated by fully integrating both a first electrode path 410 (including its first electrode 416a portion) and a second electrode path 410b (including its second electrode 416b portion) into a CMOS substrate 405. For example, such integration is performed in a CMOS foundry, or the like, by depositing metal for the electrode paths 410 on metal layers as part of the integrated circuitry of a CMOS wafer.

Integration of the electrode paths 410 includes patterning each electrode path 410 to couple with respective electrode control circuitry (not shown), as described with reference to FIG. 4A. Unlike in FIG. 4A, neither electrode path 410 is fabricated to terminate at an exposed metal contact 414. Similar to FIG. 5A, fabrication of the CMOS wafer in FIG. 6A includes fabrication of the full first electrode path 410a, including fabrication of the first electrode 416a. As illustrated, during fabrication of the CMOS wafer (e.g., at the CMOS foundry), the first electrode 416a metal is deposited and patterned in the last metal layer of the CMOS wafer. Integration of the first electrode 416a can include patterning a sacrificial layer (e.g., of silicon oxide, or the like), depositing the first electrode 416a metal over the sacrificial layer, patterning relief holes in the first electrode 416a, and etching the sacrificial layer using the relief holes to form an acoustic cavity 425 under the first electrode 416a. As described above, a conformal layer (e.g., of the first electrode 416a metal and/or the piezoelectric element 430 material) can be used to seal the relief holes to form the acoustic cavity 425 as a “vacuum” cavity in some implementations. Fabrication of the CMOS wafer in FIG. 6A also includes fabrication of the full second electrode path 410b, including fabrication of the second electrode 416b. As with the first electrode 416a, the second electrode 416b metal is deposited and patterned in the last metal layer of the CMOS wafer during fabrication. Thus, upon completion of processing of the CMOS wafer, in the location of each integrated MEMS-CMOS ultrasonic sensor element 500, there is a fully formed and exposed first electrode 416a (patterned above an acoustic cavity 425) of a first electrode path 410a, and a fully formed and exposed second electrode 416b of a second electrode path 410b.

Turning to FIGS. 6B and 6C, after the CMOS wafer is processed, post-processing can be performed to fabricate remaining portions of the integrated MEMS-CMOS ultrasonic sensor element 600. The remaining process of FIGS. 6B and 6C can be similar to that of FIGS. 4C and 4E described above. The piezoelectric element 430 can be formed by depositing a piezoelectric thin film on top of the first electrode 416a (and the acoustic cavity 425) and the second electrode 416b, and patterning the thin film material to form a piezoelectric transducer. FIG. 6C shows one or more additional layers optionally deposited on the wafer (illustrated generally as additional layers 450). In some implementations, the surface of the sensor wafer is then planarized and/or otherwise finished. The resulting integrated MEMS-CMOS ultrasonic sensor element 600 is different from those of FIGS. 4A-5C in that the integrated MEMS-CMOS ultrasonic sensor element 600 has both the first electrode 416a and the second electrode 416b on a same side of the piezoelectric element 430. In such implementations, as illustrated, the electrodes 416 do not sandwich the piezoelectric transducer; rather, the electrodes 416 are fabricated to contact the piezoelectric element 430 in multiple locations. For example, the first electrode 416a can be formed as a circular region with the second electrode 416b formed as a concentric ring around at least some of the first electrode 416a.

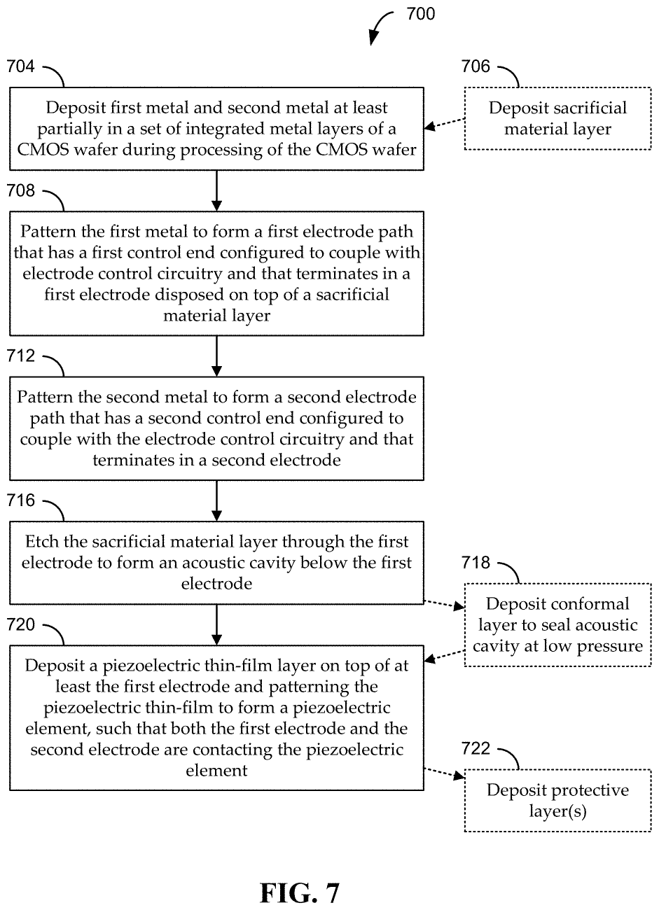

FIG. 7 shows a flow diagram of an illustrative method 700 for manufacturing an integrated micro-electromechanical system and complementary metal-oxide semiconductor (MEMS-CMOS) ultrasonic sensor element, according to various embodiments described herein. Embodiments begin at stage 704 by depositing first metal and second metal at least partially in a set of integrated metal layers of a CMOS wafer during processing of the CMOS wafer. At stage 708, embodiments can pattern the first metal to form a first electrode path that has a first control end configured to couple with electrode control circuitry and that terminates in a first electrode disposed on top of a sacrificial material layer. At stage 712, embodiments can pattern the second metal to form a second electrode path that has a second control end configured to couple with the electrode control circuitry and that terminates in a second electrode.

At stage 716, embodiments can etch the sacrificial material layer through the first electrode to form an acoustic cavity below the first electrode. At stage 720, embodiments can deposit a piezoelectric thin-film layer on top of at least the first electrode and patterning the piezoelectric thin-film to form a piezoelectric element, such that both the first electrode and the second electrode are contacting the piezoelectric element. Some embodiments can also include depositing, at stage 722, one or more protective layers on top of at least the piezoelectric element (e.g., and on top of the second electrode in embodiments where the second electrode is on top of the piezoelectric element). Embodiments can also include planarizing and/or otherwise finishing the sensor element.

In some embodiments, patterning the first metal at stage 708 includes: patterning the first metal, during the processing of the CMOS wafer, to form a first portion of the first electrode path that terminates in a first exposed metal contact on an upper-most metal layer of the CMOS wafer (e.g., as illustrated in FIG. 4A); depositing additional first metal of the first electrode path in a layer on top of the sacrificial material layer to electrically couple with the first exposed metal contact (e.g., as illustrated in FIG. 4B); and patterning the additional first metal, subsequent to the depositing the additional first metal, to form the first electrode (e.g., also as illustrated in FIG. 4B). In some such embodiments, a sacrificial metal layer can be deposited at stage 706, subsequent to the processing of the CMOS wafer and prior to the depositing the additional first metal, such as shown in FIG. 4B. In some such embodiments, patterning the second metal at stage 712 includes: patterning the second metal, during the processing of the CMOS wafer, to form a first portion of the second electrode path that terminates in a second exposed metal contact on the upper-most metal layer of the CMOS wafer (e.g., as illustrated in FIG. 4A); depositing additional second metal of the second electrode path in a layer on top of the piezoelectric element to electrically couple with the second exposed metal contact (e.g., as illustrated in FIG. 4D); and patterning the additional second metal, subsequent to the depositing the additional second metal, to form the second electrode, thereby sandwiching the piezoelectric element between the first electrode and the second electrode (e.g., as also illustrated in FIG. 4D).

In some embodiments, depositing the first metal at stage 704 includes depositing a portion of the first metal in an upper-most metal layer of the CMOS wafer; and the patterning the first metal at stage 408 includes patterning the portion of the first metal, during the processing of the CMOS wafer, to form the first electrode on the upper-most metal layer (e.g., as illustrated in FIG. 5A or 6A). In some such embodiments, a sacrificial metal layer can be deposited at stage 706, in a layer of the CMOS wafer below the upper-most metal layer, prior to the depositing the portion of the first metal in the upper-most metal layer; such that the etching causes the acoustic cavity to be integrated in the CMOS wafer, such as shown in FIG. 5A or 6A. In some such embodiments, patterning the second metal at stage 712 includes: patterning the second metal, during the processing of the CMOS wafer, to form a first portion of the second electrode path that terminates in a second exposed metal contact on the upper-most metal layer of the CMOS wafer (e.g., as illustrated in FIG. 5A); depositing additional second metal of the second electrode path in a layer on top of the piezoelectric element to electrically couple with the second exposed metal contact (e.g., as illustrated in FIG. 5B); and patterning the additional second metal, subsequent to the depositing the additional second metal, to form the second electrode, thereby sandwiching the piezoelectric element between the first electrode and the second electrode (e.g., as also illustrated in FIG. 5B). In other such embodiments, depositing the second metal in stage 704 includes depositing a portion of the second metal in an upper-most metal layer of the CMOS wafer; and patterning the second metal in stage 712 includes patterning the portion of the second metal, during the processing of the CMOS wafer, to form the second electrode next to the first electrode on the upper-most metal layer (e.g., as illustrated in FIG. 6A). In such embodiments, depositing the piezoelectric thin-film layer at stage 720 can be performed such that the piezoelectric element is patterned on top of both the first electrode and the second electrode (e.g., as illustrated in FIG. 6B).

In some embodiments, etching the sacrificial material layer in stage 716 includes patterning relief holes in a portion of the first metal forming the first electrode, and etching the sacrificial material layer via the relief holes to form the acoustic cavity. Some such embodiments can further include depositing, at stage 718, subsequent to the etching in stage 716, a conformal layer on top of the first electrode to seal the relief holes, thereby forming the acoustic cavity as a low-pressure (e.g., vacuum) cavity. In some implementations, the conformal layer is a layer of the first metal used to form the first electrode. In other implementations, the conformal layer is a layer of the piezoelectric thin-film material (e.g., a separate layer of the piezoelectric thin-film material, or the piezoelectric element itself).

Temperature Stabilization

One limitation of piezoelectric-based (i.e., PMUT-type) ultrasonic sensors is that the piezoelectric transducer (e.g., the active thin-film layer of aluminum nitride) can be sensitive to temperature variations. As described above, the piezoelectric transducer in such sensors operates by mechanical deformation. When transmitting, the piezoelectric transducer converts electrical signals into mechanical vibration, which produces ultrasonic waves. When receiving (detecting), the piezoelectric transducer detects reflected ultrasonic waves as mechanical vibrations, which it converts back to electrical signals. Typically, the reflected ultrasonic waves have relatively little energy, and they tend to produce a relatively weak signal. As the temperature of the piezoelectric transducer drops (e.g., in cold environments), the piezoelectric material can stiffen. This can dampen the amount of mechanical deformation caused by the reflected ultrasonic energy, which can further weaken the detected signal.

Some embodiments can integrate MEMS heating elements into the ultrasonic sensor design to heat the sensor, when and where appropriate. As described below, the MEMS heating can be configured to gain and lose thermal energy very quickly, such as within a few milliseconds (e.g. or tens of milliseconds). Some embodiments can be configured to maintain the temperature of at least the piezoelectric transducer at around 10 degrees Celsius, and or to provide heating when a temperature is detected to fall to some threshold level below 10 degrees Celsius (or above any desired temperature threshold). The MEMS heating can also be configured to consume only a few milliWatts and to operate for very short windows of time, so as to have minimal impact to a power source (e.g., to battery life) even across a relatively large array.

Some embodiments implement the MEMS heating by using the metal layers in the CMOS wafer to form the MEMS heating elements. Other embodiments additionally or alternatively include MEMS heating elements above the piezoelectric transducer, such as in the protective layer. Some embodiments implement a separate MEMS heater as part of producing each (e.g., of some or all) of the detector elements of the sensor array. Other embodiments implement a single MEMS heater for groups of multiple detector elements (e.g., for regional heating). Some embodiments further include heating for one or more additional layers proximate to the sensor. For example, the PDMS layer, glass top layer, display layers, etc. can also be affected by temperature changes, which can impact the responsiveness, resonance and/or other properties of the ultrasonic sensor. As such, some embodiments include heating elements to heat those additional layers.

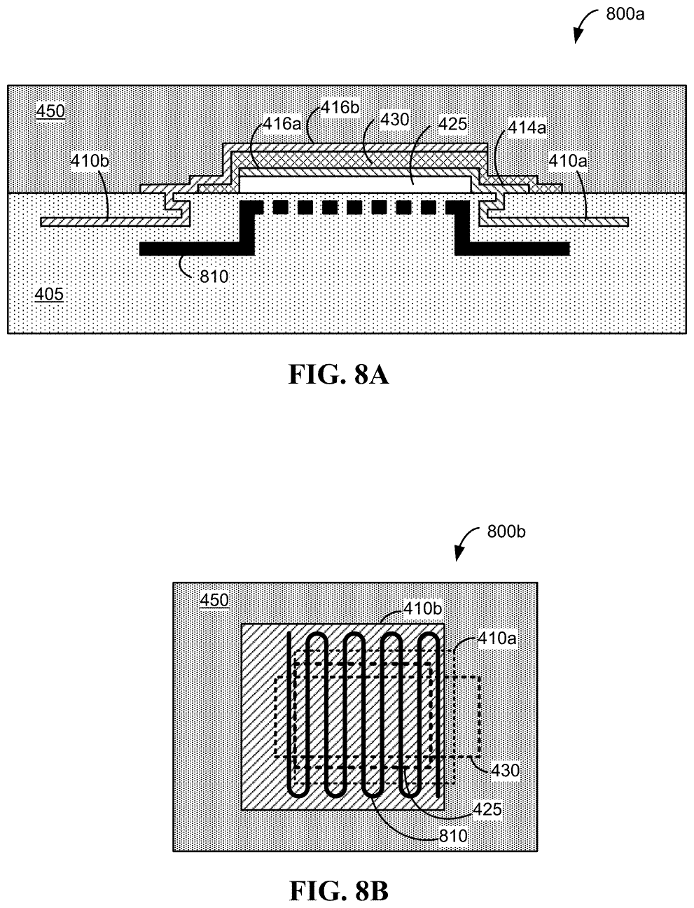

FIGS. 8A and 8B show side and top views, respectively, of a first illustrative implementation of a novel integrated MEMS-CMOS ultrasonic sensor element 800 with integrated temperature stabilization. The integrated MEMS-CMOS ultrasonic sensor element 800 is illustrated substantially as the sensor element 400 described with reference to FIG. 4E, with the addition of integrated MEMS heating elements 810. Though illustrated in that context, the MEMS heating elements 810 can alternatively be integrated with implementations shown in any FIG. 5C or FIG. 6C, and/or any variations thereof. In some embodiments, the MEMS heating elements 810 are integrated with conventional PMUT architectures, such as those described with reference to FIG. 3.

As described herein, MEMS ultrasonic sensor components generally include a first electrode 416a (as part of a first electrode path 410a), a second electrode 416b (as part of a second electrode path 410b), a piezoelectric element 430, and an acoustic cavity 425. As described with reference to FIGS. 4A-6C, some or all of the electrode paths 410 and/or acoustic cavity 425 can be integrated in the manufacturing of the CMOS wafer (e.g., with one or both electrodes 416 in the top metal layer of the CMOS wafer). As described above, the cavity can be an air cavity, a low-pressure cavity, or a vacuum cavity. The piezoelectric thin film (the piezoelectric element 430) can be deposited on top of at least the first electrode 416a. In some embodiments, the piezoelectric element 430 is deposited also on top of the second electrode 416b. In other embodiments, the second electrode 416b is deposited on top of the piezoelectric element 430, such that the piezoelectric element 430 is sandwiched between the first electrode 416a and the second electrode 416b. In some embodiments, one or more additional layers are deposited on the wafer, such as one or more protective layers 450 (e.g., made of polysilicon); and the surface of the sensor wafer can then planarized and/or otherwise finished.

The MEMS heating elements 810 include metal deposited in a metal layer of the CMOS wafer and patterned to form metal heating elements. The metal heating elements can be patterned as heating wires, heating coils, or any other suitable metal structures. Ends of the MEMS heating elements 810 can be coupled with heating control circuitry (not explicitly shown). The heating control circuitry can include any suitable electronic components to controllably cause heating of the MEMS heating elements 810. For example, the heating control circuitry can apply voltage across the MEMS heating elements 810, and resistance of the MEMS heating elements 810 can cause the metal heating elements to heat up and radiate heat energy. In some implementations, the MEMS heating elements 810 are patterned to terminate in one or more exposed electrical contacts, which can be coupled with a non-integrated implementation of the heating control circuitry. In other implementations, some or all of the heating control circuitry is integrated with the CMOS wafer, and the MEMS heating elements 810 are patterned to electrically couple with the integrated circuitry.

The MEMS heating elements 810 can be located in any suitable position that provides heating to some or all of the piezoelectric element 430. The illustrated implementation shows the MEMS heating elements 810 disposed directly below the piezoelectric element 430 and the acoustic cavity 425. Other implementations of the MEMS heating elements 810 can include one or more MEMS heating sub-elements disposed above and/or below some or all of the piezoelectric element 430.

In the illustrated embodiment, the MEMS heating elements 810 are implemented as a micro serpentine metal coil embedded in the CMOS wafer. For example, MEMS heater metal lines are formed in a serpentine path on a metal layer that was deposited during the fabrication of the CMOS wafer. An illustrative pattern of overlap can be seen in the top view of FIG. 8B. As shown, all the PMUT structures overlap to form a region where the piezoelectric element 430 is sandwiched between the first electrode 416a and the second electrode 416b directly over the acoustic cavity 425; and the serpentine MEMS heater metal lines (the MEMS heating elements 810) can be seen disposed at least below the cavity (the MEMS heating elements 810 are drawn with solid lines for added clarity, even though the MEMS heating elements 810 are below other structures shown in the top view). The heating wires can be deposited in any suitable shape or pattern. For example, the wires may form a spiral shape rather than a serpentine shape.

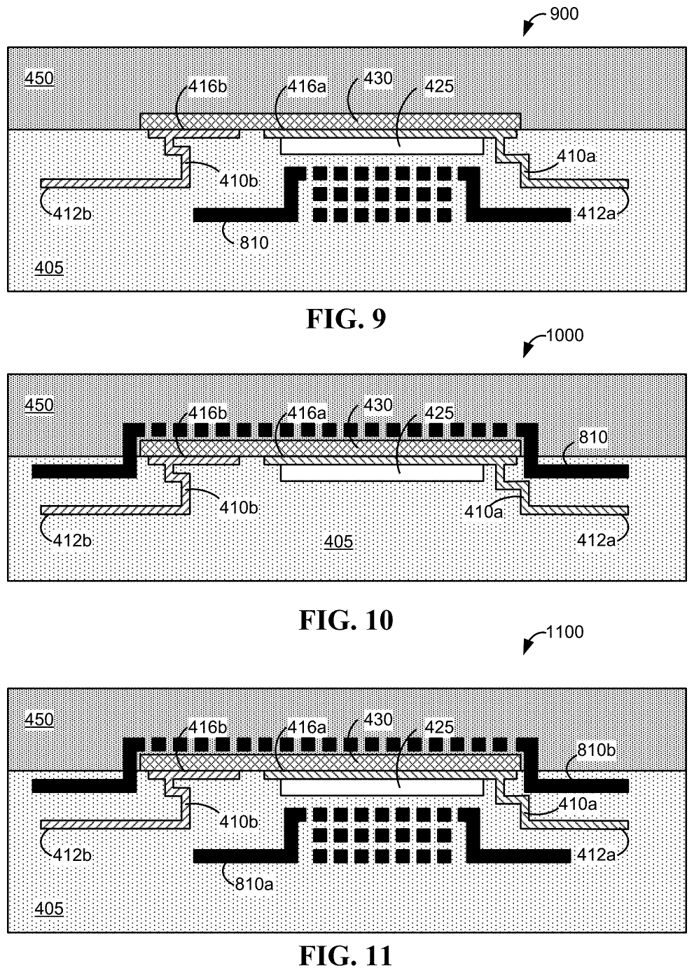

The MEMS heating elements 810 can be implemented in various ways according to different embodiments. For example, FIG. 9 shows a second illustrative implementation of a novel integrated MEMS-CMOS ultrasonic sensor element 900 with integrated temperature stabilization. The integrated MEMS-CMOS ultrasonic sensor element 900 is similar to the integrated MEMS-CMOS ultrasonic sensor element 600 illustrated in FIG. 6C, except with the addition of the MEMS heating elements 810. The MEMS heating elements 810 of FIG. 9 is similar to the one illustrated in FIG. 8A with additional layers of MEMS heating wires (i.e., as multiple MEMS heating sub-elements). For example, the MEMS heater metal lines are formed from multiple metal layers that were deposited during the fabrication of the CMOS wafer, and the multiple MEMS heater coils are connected either in parallel or in series to optimize the heat transfer to the piezoelectric layer to stabilize its temperature. In such implementations, each layer can be patterned in the same, or different ways. In one implementation, each layer is patterned as a serpentine metal coil, with each layer oriented differently and/or having differently spaced coils relative to its adjacent layers. In another implementation, one layer is patterned as a serpentine coil, and another layer is patterned as a spiral coil.

FIG. 10 shows a third illustrative implementation of a novel integrated MEMS-CMOS ultrasonic sensor element 1000 with integrated temperature stabilization. The sensor element 1000 is similar to the sensor element 900 illustrated in FIG. 9, except that the MEMS heating elements 810 are formed above the piezoelectric element 430. For example, the CMOS wafer is fabricated with one or more exposed contacts for the MEMS heating elements 810, and the MEMS heating elements 810 are deposited on top of the piezoelectric element 430 (e.g., directly, or with one or more layers of material deposited between) and are patterned to electrically couple with the exposed contacts in post processing. As with the MEMS heating elements 810 implemented below the piezoelectric element 430, the MEMS heating elements 810 implemented above the piezoelectric element 430 can be implemented in one or more layers, in one or more shapes (e.g., serpentine, spiral, mesh, etc.), in one or more thickness, in one or more inter-coil spacings, and/or in any suitable manner for optimizing the heat transfer to the piezoelectric element 430 to stabilize its temperature.

FIG. 11 shows a fourth illustrative implementation of a novel integrated MEMS-CMOS ultrasonic sensor element 1100 with integrated temperature stabilization. The sensor element 1100 is essentially a combination of the implementations of FIGS. 9 and 10, implementing the MEMS heating elements 810 as multiple MEMS heating sub-elements. One set of MEMS heating sub elements of the MEMS heating elements 810 is formed on a single metal layer (e.g., as in FIG. 8A), or on multiple metal layers (e.g., as in FIG. 9) below the PMUT structures. For example, the MEMS heater metal lines are formed from one or more metal layers deposited during the fabrication of the CMOS wafer. A second set of MEMS heating sub-elements of the MEMS heating elements 810 are deposited on top of the piezoelectric transducer (e.g., as in FIG. 10). The multiple MEMS heater coils can be connected in parallel, in series, or in any suitable manner to heat the piezoelectric element 430, as desired.

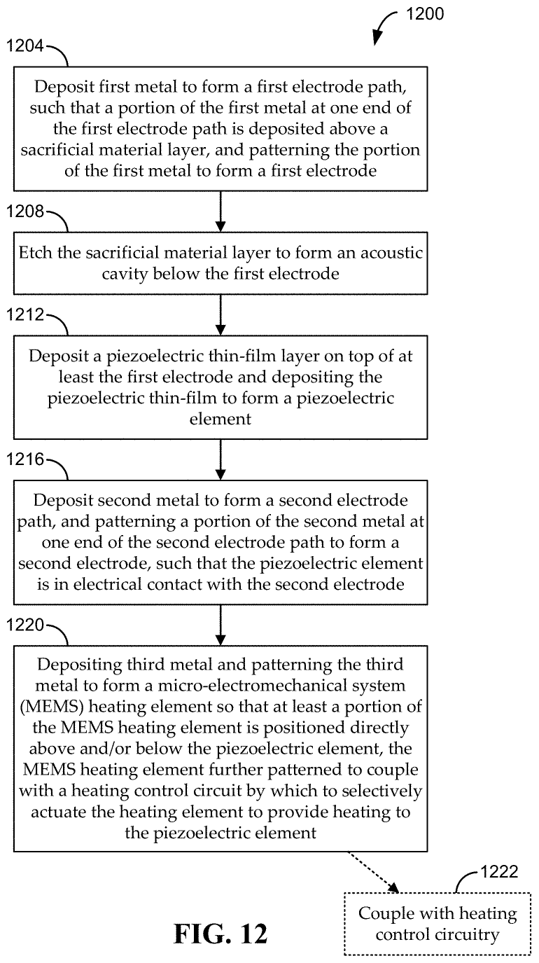

FIG. 12 shows a flow diagram of an illustrative method 1200 for manufacturing a piezoelectric micromachined ultrasonic transducer (PMUT), according to various embodiments described herein. Embodiments of the method 1200 can begin at stage 1204 by depositing first metal to form a first electrode path, such that a portion of the first metal at one end of the first electrode path is deposited above a sacrificial material layer, and patterning the portion of the first metal to form a first electrode. At stage 1208, embodiments can etch the sacrificial material layer to form an acoustic cavity below the first electrode. At stage 1212, embodiments can deposit a piezoelectric thin-film layer on top of at least the first electrode and depositing the piezoelectric thin-film to form a piezoelectric element. At stage 1216, embodiments can deposit second metal to form a second electrode path, and patterning a portion of the second metal at one end of the second electrode path to form a second electrode, such that the piezoelectric element is in electrical contact with the second electrode.

At stage 1220, embodiments can deposit third metal and patterning the third metal to form a micro-electromechanical system (MEMS) heating element so that at least a portion of the MEMS heating element is positioned directly above and/or below the piezoelectric element, the MEMS heating element further patterned to couple with a heating control circuit by which to selectively actuate the heating element to provide heating to the piezoelectric element. In some embodiments, the third metal is patterned to form the MEMS heating element to include at least one serpentine heating wire and/or at least one spiral heating wire. In some embodiments, the third metal is patterned to form the MEMS heating element to include: a first one or more MEMS heating sub-elements positioned below the acoustic cavity to provide the heating to the piezoelectric element from below; and a second one or more MEMS heating sub-elements positioned above the piezoelectric element to provide the heating to the piezoelectric element from above. In some embodiments, the third metal is patterned to form the MEMS heating element to include a stack of MEMS heating sub-elements positioned directly above and/or below the piezoelectric element.

In some embodiments, the MEMS heating element (e.g., one or more MEMS heating sub-elements) is electrically coupled with the heating control circuitry at stage 1222. In some such embodiments, the heating control circuit is integrated into a CMOS wafer, and the depositing the third metal is on one or more metal layers of the CMOS wafer, such that the MEMS heating element is integrated into the CMOS wafer. The MEMS heating element can be further patterned to couple with the heating control circuit via integrated electrical routings of the CMOS wafer (e.g., metal layer routings, vias, etc.). In other such embodiments, the heating control circuit is integrated into a CMOS wafer and electrically accessible via exposed metal contacts of the CMOS wafer, and the MEMS heating element can be electrically coupled with the heating control circuit via the exposed metal contacts.

While this disclosure contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

A recitation of “a”, “an” or “the” is intended to mean “one or more” unless specifically indicated to the contrary. Ranges may be expressed herein as from “about” one specified value, and/or to “about” another specified value. The term “about” is used herein to mean approximately, in the region of, roughly, or around. When the term “about” is used in conjunction with a numerical range, it modifies that range by extending the boundaries above and below the numerical values set forth. In general, the term “about” is used herein to modify a numerical value above and below the stated value by a variance of 10%. When such a range is expressed, another embodiment includes from the one specific value and/or to the other specified value. Similarly, when values are expressed as approximations, by use of the antecedent “about,” it will be understood that the specified value forms another embodiment. It will be further understood that the endpoints of each of the ranges are included with the range.

All patents, patent applications, publications, and descriptions mentioned here are incorporated by reference in their entirety for all purposes. None is admitted to be prior art.

What is claimed is:

1. A method of manufacturing an integrated micro-electromechanical system and complementary metal-oxide semiconductor (MEMS-CMOS) ultrasonic sensor element, the method comprising:
depositing first metal and second metal at least partially in a set of integrated metal layers of a CMOS wafer during processing of the CMOS wafer;
patterning the first metal to form a first electrode path that has a first control end configured to couple with electrode control circuitry and that terminates in a first electrode disposed on top of a sacrificial material layer;
patterning the second metal to form a second electrode path that has a second control end configured to couple with the electrode control circuitry and that terminates in a second electrode;
etching the sacrificial material layer through the first electrode to form an acoustic cavity below the first electrode; and
depositing a piezoelectric thin-film layer on top of at least the first electrode and patterning the piezoelectric thin-film to form a piezoelectric element, such that both the first electrode and the second electrode are contacting the piezoelectric element.

2. The method of claim 1, wherein the patterning the first metal comprises:
patterning the first metal, during the processing of the CMOS wafer, to form a first portion of the first electrode path that terminates in a first exposed metal contact on an upper-most metal layer of the CMOS wafer;
depositing additional first metal of the first electrode path in a layer on top of the sacrificial material layer to electrically couple with the first exposed metal contact; and
patterning the additional first metal, subsequent to the depositing the additional first metal, to form the first electrode.

3. The method of claim 2, further comprising:
depositing the sacrificial material layer, subsequent to the processing of the CMOS wafer and prior to the depositing the additional first metal.

4. The method of claim 2, wherein the patterning the second metal comprises:
patterning the second metal, during the processing of the CMOS wafer, to form a first portion of the second electrode path that terminates in a second exposed metal contact on the upper-most metal layer of the CMOS wafer;
depositing additional second metal of the second electrode path in a layer on top of the piezoelectric element to electrically couple with the second exposed metal contact; and
patterning the additional second metal, subsequent to the depositing the additional second metal, to form the second electrode, thereby sandwiching the piezoelectric element between the first electrode and the second electrode.

5. The method of claim 1, wherein:
the depositing the first metal comprises depositing a portion of the first metal in an upper-most metal layer of the CMOS wafer; and
the patterning the first metal comprises patterning the portion of the first metal, during the processing of the CMOS wafer, to form the first electrode on the upper-most metal layer.

6. The method of claim 5, further comprising:
depositing the sacrificial material layer in a layer of the CMOS wafer below the upper-most metal layer, prior to the depositing the portion of the first metal in the upper-most metal layer, such that the etching causes the acoustic cavity to be integrated in the CMOS wafer.

7. The method of claim 5, wherein the patterning the second metal comprises:
patterning the second metal, during the processing of the CMOS wafer, to form a first portion of the second electrode path that terminates in a second exposed metal contact on the upper-most metal layer of the CMOS wafer;
depositing additional second metal of the second electrode path in a layer on top of the piezoelectric element to electrically couple with the second exposed metal contact; and
patterning the additional second metal, subsequent to the depositing the additional second metal, to form the second electrode, thereby sandwiching the piezoelectric element between the first electrode and the second electrode.

8. The method of claim 5, wherein:
the depositing the second metal comprises depositing a portion of the second metal in an upper-most metal layer of the CMOS wafer;
the patterning the second metal comprises patterning the portion of the second metal, during the processing of the CMOS wafer, to form the second electrode next to the first electrode on the upper-most metal layer; and
the depositing the piezoelectric thin-film layer is such that the piezoelectric element is patterned on top of both the first electrode and the second electrode.

9. The method of claim 1, wherein the etching the sacrificial material layer comprises:
patterning relief holes in a portion of the first metal forming the first electrode;
etching the sacrificial material layer via the relief holes to form the acoustic cavity.

10. The method of claim 9, further comprising:
depositing, subsequent to the etching, a conformal layer of the first metal on top of the first electrode to seal the relief holes, thereby forming the acoustic cavity as a low-pressure cavity.

11. The method of claim 9, further comprising:
depositing, subsequent to the etching, a conformal layer of the piezoelectric thin-film on top of the first electrode to seal the relief holes, thereby forming the acoustic cavity as a low-pressure cavity.

12. The method of claim 1, wherein:
the patterning the second metal forms the second electrode to be disposed not on top of the sacrificial material layer.

13. The method of claim 1, wherein the piezoelectric thin-film layer is a layer of aluminum nitride.

14. The method of claim 1, further comprising:
depositing one or more protective layers on top of at least the piezoelectric element.

15. An integrated micro-electromechanical system and complementary metal-oxide semiconductor (MEMS-CMOS) ultrasonic sensor element comprising:
a first electrode path at least partially integrated within a set of metal layers of a CMOS wafer, the first electrode path having a first control end configured to couple with electrode control circuitry, and the first electrode path terminating in a first electrode disposed on top of an acoustic cavity;
a piezoelectric thin-film layer disposed on top of at least the first electrode and patterned to form a piezoelectric element; and
a second electrode path at least partially integrated within the set of metal layers of the CMOS wafer, the second electrode path having a second control end configured to couple with the electrode control circuitry, and the second electrode path terminating in a second electrode in contact with the piezoelectric element.

16. The integrated MEMS-CMOS ultrasonic sensor element of claim 15, wherein the first electrode path comprises:
a first portion integrated within the set of metal layers of the CMOS wafer and terminating, opposite the first control end, at an exposed metal contact in an upper-most metal layer of the CMOS wafer; and
a second portion not integrated within the CMOS wafer, the second portion electrically coupled with the exposed metal contact and patterned to form the first electrode.

17. The integrated MEMS-CMOS ultrasonic sensor element of claim 15, wherein:
the first electrode is patterned in an upper-most metal layer of the CMOS wafer; and
the acoustic cavity is formed by etching a sacrificial material layer below the first electrode via relief holes patterned in the first electrode, such that the acoustic cavity is integrated in the CMOS wafer.

18. The integrated MEMS-CMOS ultrasonic sensor element of claim 17, wherein:
the second electrode is patterned next to the first electrode in the upper-most metal layer of the CMOS wafer; and
the piezoelectric thin-film layer is disposed on top of both the first electrode and the second electrode.

19. The integrated MEMS-CMOS ultrasonic sensor element of claim 15, wherein the first electrode is in contact with a bottom side of the piezoelectric element, and the second electrode is in contact with a top side of the piezoelectric element, such that the piezoelectric element is sandwiched between the first electrode and the second electrode.

20. The integrated MEMS-CMOS ultrasonic sensor element of claim 15, wherein the first electrode and the second electrode are in contact with a same side of the piezoelectric element.
